(19) United States
(12) Patent Application Publication
(10) Pub. No.: US 2026/0006969 A1
(43) Pub. Date: Jan. 1, 2026

(54) DISPLAY DEVICE, METHOD OF MANUFACTURING THE DISPLAY DEVICE, AND ELECTRONIC DEVICE

(71) Applicant: Samsung Display Co., LTD., Yongin-si (KR)

(72) Inventors: Moon Won CHANG, Yongin-si (KR); Byoung Yong KIM, Yongin-si (KR); Jae Gwang UM, Yongin-si (KR); Tae Hee LEE, Yongin-si (KR)

(73) Assignee: Samsung Display Co., LTD., Yongin-si (KR)

(21) Appl. No.: 19/175,370

(22) Filed: Apr. 10, 2025

(30) Foreign Application Priority Data
Jun. 27, 2024 (KR) 10-2024-0084676

(51) Int. Cl. H10H 29/80; H10H 29/01

(52) U.S. Cl. CPC H10H 29/8325; H10H 29/012; H10H 29/032

(57) ABSTRACT

Provided is a display device including a substrate and a display element layer disposed on the substrate. The display element layer includes an anode electrode and a cathode electrode, a first bonding metal disposed between the anode electrode and the cathode electrode, a first reflective electrode disposed on the anode electrode, a second reflective electrode disposed on the cathode electrode, a light emitting element including a first element electrode, a second element electrode, and a second bonding metal, a first transparent electrode electrically connecting the first reflective electrode and the first element electrode to each other, and a second transparent electrode electrically connecting the second reflective electrode and the second element electrode to each other.

### CROSS-REFERENCE TO RELATED APPLICATION(S)

The present application claims priority to and benefits of Korean patent application No. 10-2024-0084676 under 35 U.S.C. § 119, filed on Jun. 27, 2024, in the Korean Intellectual Property Office, the entire contents of which are incorporated herein by reference.

### BACKGROUND

### 1. Technical Field

The disclosure generally relates to a display device, a method of manufacturing a display device, and an electronic device including a display device. More particularly, the disclosure relates to a display device having improved light output efficiency and a method of manufacturing the display device.

### 2. Description of the Related Art

With the development of information technologies, the importance of a display device which is a connection medium between a user and information increases. Accordingly, display devices such as a liquid crystal display device, an organic light emitting display device, and an inorganic light emitting display device are increasingly used.

When an organic material having adhesion is used to fix a light emitting element to a pixel circuit layer, problems may occur, such as deterioration of the adhesion and sticking of a foreign matter due to the adhesion.

### SUMMARY

Embodiments may provide a display device, a method of manufacturing a display device, and an electronic device including a display device, in which a light emitting element is fixed without an organic material having adhesion.

In accordance with an aspect of the disclosure, a display device may include: a substrate; and a display element layer disposed on the substrate, wherein the display element layer includes: an anode electrode and a cathode electrode; a first bonding metal disposed between the anode electrode and the cathode electrode; a first reflective electrode disposed on the anode electrode; a second reflective electrode disposed on the cathode electrode; a light emitting element including a first element electrode, a second element electrode, and a second bonding metal; a first transparent electrode electrically connecting the first reflective electrode to the first element electrode; and a second transparent electrode electrically connecting the second reflective electrode to the second element electrode.

The first bonding metal and the second bonding metal may overlap each other in a plan view.

The anode electrode, the cathode electrode, and the first bonding metal may be spaced apart from each other.

The second bonding metal may be disposed under the light emitting element. A metallic alloy may be formed in an area in which the first bonding metal and the second bonding metal are in contact with each other.

The first bonding metal may include copper (Cu), and the second bonding metal may include a combination of tin (Sn), silver (Ag), and copper (Cu).

The display element layer may be disposed on the substrate in a thickness direction. The first element electrode and the second element electrode may face in the upper direction. The first transparent electrode may overlap the first element electrode in a plan view. The second transparent electrode may overlap the second element electrode in a plan view.

The anode electrode, the cathode electrode, and the first bonding metal may be disposed in a same layer. The anode electrode and the cathode electrode may include a same conductive material.

In accordance with another aspect of the disclosure, an electronic device may include: a display device and a substrate, wherein the display device includes: a substrate; and a display element layer disposed on the substrate, wherein the display element layer includes: an anode electrode and a cathode electrode; a light emitting element including a first element electrode, a second element electrode, a first sub-bonding metal, and a second sub-bonding metal; a first transparent electrode electrically connecting the anode electrode to the first element electrode; and a second transparent electrode electrically connecting the cathode electrode to the second element electrode, and wherein the first sub-bonding metal and the second sub-bonding metal are disposed under the light emitting element.

In a plan view, the first sub-bonding metal may overlap the anode electrode, and the second sub-bonding metal may overlap the cathode electrode.

A metallic alloy may be formed in an area in which the first sub-bonding metal and the anode electrode are in contact with each other, and another metallic alloy may be formed in an area in which the second sub-bonding metal and the cathode electrode are in contact with each other.

Each of the first sub-bonding metal and the second sub-bonding metal may include a combination of tin (Sn), silver (Ag), and copper (Cu).

The display element layer may be disposed on the substrate in a thickness direction. The first element electrode and the second element electrode may face in the upper direction. The first transparent electrode may overlap the first element electrode in a plan view. The second transparent electrode may overlap the second element electrode in a plan view.

The anode electrode and the cathode electrode may be disposed in a same layer, and include a same conductive material.

In accordance with still another aspect of the disclosure, a method of manufacturing a display device may include: manufacturing a pixel circuit layer disposed on a substrate; and manufacturing a display element layer disposed on the pixel circuit layer, wherein the manufacturing of the display element layer includes; patterning an anode electrode and a cathode electrode disposed on the pixel circuit layer; patterning a first reflective electrode electrically connected to the anode electrode and a second reflective electrode electrically connected to the cathode electrode; patterning a first bonding metal disposed between the anode electrode and the cathode electrode; and disposing, on the pixel circuit layer, a light emitting element including a first element electrode, a second element electrode, and a second bonding metal.

In a cross-sectional view, the first bonding metal may be disposed in a space in which the anode electrode and the cathode electrode are spaced apart from each other.

In a cross-sectional view, the anode electrode, the cathode electrode, and the first bonding metal may be spaced apart from each other.

The disposing of the light emitting element including the first element electrode, the second element electrode, and the second bonding metal on the pixel circuit layer may include: forming the second bonding metal between the light emitting element and the first bonding metal.

The method may further include: irradiating laser between the first bonding metal and the second bonding metal; and generating a metallic alloy in an area in which the first bonding metal and the second bonding metal are in contact with each other by irradiating the laser.

The first bonding metal may include copper (Cu), and the second bonding metal may include a combination of tin (Sn), silver (Ag), and copper (Cu).

The manufacturing of the display element layer may further include patterning a first transparent electrode electrically connected to the first reflective electrode and a second transparent electrode electrically connected to the second reflective electrode after the light emitting element is disposed on the pixel circuit layer.

An electronic device includes a display device and a substrate, wherein the display device includes the display element layer, and the display element layer is disposed on the substrate.

The electronic device is at least one of a smart watch, a mobile phone, a smartphone, a portable computer, a tablet personal computer (PC), a watch phone, an automotive display, a smart glass, a portable multimedia player (PMP), a navigation system, an ultra-mobile computer (UMPC), a head mounted display (HMD) device, a virtual reality (VR) device, a mixed reality (MR) device, and an augmented reality (AR) device.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic block diagram illustrating an embodiment of a display device.

FIG. 2 is a schematic block diagram illustrating an embodiment of any one of sub-pixels shown in FIG. 1.

FIG. 3 is a schematic plan view illustrating an embodiment of a display panel shown in FIG. 1.

FIG. 4 is a schematic cross-sectional view illustrating an embodiment of the display panel shown in FIG. 3.

FIG. 5 is a schematic cross-sectional view illustrating another embodiment of the display panel shown in FIG. 3.

FIG. 6 is a schematic plan view illustrating an embodiment of any one of pixels shown in FIG. 3.

FIG. 7 is a schematic cross-sectional view illustrating an embodiment of the disclosure, which is taken along line A-A′ shown in FIG. 6.

FIG. 8 is a schematic cross-sectional view illustrating a first light emitting element shown in FIG. 7.

FIG. 9 is a schematic flowchart illustrating a method of manufacturing a display device in accordance with an embodiment of the disclosure.

FIG. 10 is a schematic flowchart illustrating a step of manufacturing a display element layer in accordance with an embodiment of the disclosure.

FIG. 11 is a schematic flowchart illustrating a step of disposing a light emitting element in accordance with an embodiment of the disclosure.

FIGS. 12 to 14 are schematic cross-sectional views illustrating process steps according to the step shown in FIG. 11.

FIG. 15 is a cross-sectional view illustrating another embodiment of the disclosure, which is taken along line A-A′ shown in FIG. 6.

FIG. 16 is a schematic block diagram illustrating an embodiment of a display system.

FIGS. 17 to 20 are schematic perspective views illustrating application examples of the display system shown in FIG. 16.

### DETAILED DESCRIPTION OF THE EMBODIMENTS

Hereinafter, embodiments of the disclosure will be described in more detail with reference to the accompanying drawings. In the description below, only a necessary part to understand an operation according to the disclosure is described and the descriptions of other parts are omitted in order not to unnecessarily obscure subject matters of the disclosure. The disclosure is not limited to exemplary embodiments described herein, but may be embodied in various different forms. Rather, exemplary embodiments described herein are provided to thoroughly and completely describe the disclosed contents and to sufficiently transfer the ideas of the disclosure to a person of ordinary skill in the art.

In the entire specification, when an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that when a component “includes” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure are described here with reference to schematic diagrams of ideal embodiments (and an intermediate structure) of the disclosure, so that changes in a shape as shown due to, for example, manufacturing technology and/or a tolerance may be expected. Therefore, the embodiments of the disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

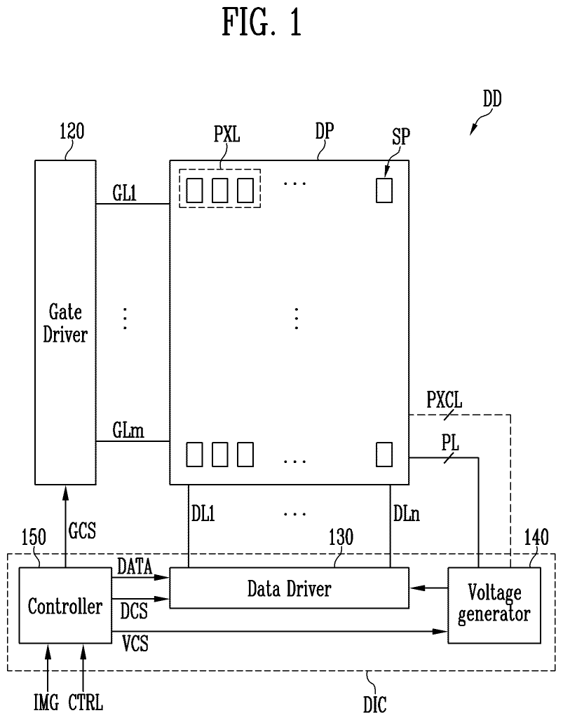

FIG. 1 is a schematic block diagram illustrating an embodiment of a display device.

Referring to FIG. 1, the display device DD may include a display panel DP, a gate driver 120, a data driver 130, a voltage generator 140, and a controller 150.

The display panel DP may include sub-pixels SP. The sub-pixels SP may be electrically connected to the gate driver 120 through first to mth gate lines GL1 to GLm. The sub-pixels SP may be electrically connected to the data driver 130 through first to nth data lines DL1 to DLn.

The sub-pixels SP may generate lights of two or more colors. For example, each of the sub-pixels SP may generate lights of red, green, blue, cyan, magenta, yellow, white, and the like.

Two or more sub-pixels among the sub-pixels SP may constitute a pixel PXL. For example, the pixel PXL may include three sub-pixels as shown in FIG. 1. For example, the pixel PXL may emit lights of various colors with various luminances according to a combination of lights emitted from the sub-pixels included therein.

The gate driver 120 may be electrically connected to the sub-pixels SP arranged in a row direction through the first to mth gate lines GL1 to GLm. The gate driver 120 may output gate signals to the first to mth gate lines GL1 to GLm in response to a gate control signal GCS. The gate control signal GCS may include a start signal indicating a start of each frame, a horizontal synchronization signal, and the like.

The gate driver 120 may be disposed at one side of the display panel DP. However, embodiments are not limited thereto. For example, the gate driver 120 may be divided into two or more drivers which are physically and/or logically divided, and these drivers may be disposed at a side of the display panel DP and another side of the display panel DP, which is opposite to the one side. In other embodiments, the gate driver 120 may be disposed in various forms at the periphery of the display panel DP.

The data driver 130 may be electrically connected to the sub-pixels SP arranged in a column direction through the first to nth data lines DL1 to DLn. The data driver 130 may receive image data DATA and a data control signal DCS from the controller 150. The data driver 130 may operate in response to the data control signal DCS. The data control signal DCS may include a source start pulse, a source shift clock, a source output enable signal, and the like.

The data driver 130 may receive voltages from the voltage generator 140. The data driver 130 may apply data signals having grayscale voltages corresponding to the image data DATA to the first to nth data lines DL1 to DLn by using the received voltages. In case that a gate signal is applied to each of the first to mth gate lines GL1 to GLm, data signals corresponding to the image data DATA may be applied to the first to nth data line DL1 to DLm. Accordingly, corresponding sub-pixels SP may generate light corresponding to the data signals. Accordingly, an image (or images) may be displayed on the display panel DP.

The gate driver 120 and the data driver 130 may include complementary metal-oxide semiconductor (CMOS) circuit elements.

The voltage generator 140 may operate in response to a voltage control signal VCS from the controller 150. The voltage generator 140 may generate multiple voltages and provide the generated voltages to components of the display device DD. The voltage generator 140 may generate multiple voltages by receiving an input voltage from the outside of the display device DD and regulating the received voltage.

The voltage generator 140 may generate a first power voltage and a second power voltage. The generated first and second power voltages may be provided to the sub-pixels SP through power lines PL. In other embodiments, at least one of the first and second power voltages may be provided from the outside of the display device DD.

Besides, the voltage generator 140 may provide various voltages and/or signals. For example, the voltage generator 140 may provide one or more initialization voltages applied to the sub-pixels SP. For example, in a sensing operation for sensing electrical characteristics of transistors and/or light emitting elements of the sub-pixels SP, a predetermined reference voltage may be applied to the first to nth data lines DL1 to DLn, and the voltage generator 140 may generate the reference voltage and transfer the reference voltage to the data driver 130. For example, in a display operation for displaying an image on the display panel DP, common pixel control signals may be applied to the sub-pixels SP, and the voltage generator 140 may generate the pixel control signals. The voltage generator 140 may provide the pixel control signals to the sub-pixels SP through pixel control lines PXCL. In FIG. 1, it is illustrated that the pixel control lines PXCL are electrically connected between the voltage generator 140 and the display panel DP. However, embodiments are not limited thereto. For example, the pixel control lines PXCL may be electrically connected between the gate driver 120 and the display panel DP. The pixel control signals may be transferred to the sub-pixels SP from the gate driver 120 through the pixel control lines PXCL.

The controller 150 may control overall operations of the display device DD. The controller 150 may receive, from the outside, input image data IMG and a control signal CTRL corresponding thereto. The controller 150 may provide the gate control signal GCS, the data control signal DCS, and the voltage control signal VCS in response to the control signal CTRL.

The controller 150 may convert the input image data IMG to be suitable for the display device DD or the display panel DP, thereby outputting the image data DATA. The controller 150 may align the input image data IMG to be suitable for the sub-pixels SP in units of rows, thereby outputting the image data DATA.

Two or more components among the data driver 130, the voltage generator 140, and the controller 150 may be mounted on one integrated circuit. As shown in FIG. 1, the data driver 130, the voltage generator 140, and the controller 150 may be included in a driver integrated circuit DIC. The data driver 130, the voltage generator 140, and the controller 150 may be components functionally divided in one driver integrated circuit DIC. In other embodiments, at least one of the data driver 130, the voltage generator 140, and the controller 150 may be provided as a component distinguished from the driver integrated circuit DIC.

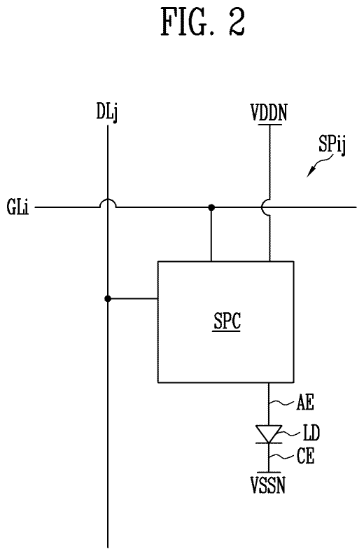

FIG. 2 is a schematic block diagram illustrating an embodiment of any one of the sub-pixels shown in FIG. 1. In FIG. 2, a sub-pixel SPij arranged on an ith row (i is an integer greater than or equal to 1 and smaller than or equal to m) and a jth column (j is an integer greater than or equal to 1 and smaller than or equal to n) among the sub-pixels SP shown in FIG. 1 is illustrated.

Referring to FIG. 2, the sub-pixel SPij may include a sub-pixel circuit SPC and a light emitting element LD.

The light emitting element LD may be electrically connected between a first power voltage node VDDN and a second power voltage node VSSN. The first power voltage node VDDN may be electrically connected to one of the power lines PL shown in FIG. 1, to receive a first power voltage. The second power voltage node VSSN may be electrically connected to another of the power lines PL, to receive a second power voltage. The first power voltage may have a voltage level higher than a voltage level of the second power voltage.

The light emitting element LD may be electrically connected between an anode electrode AE and a cathode electrode CE. The anode electrode AE may be electrically connected to the first power voltage node VDDN through the sub-pixel circuit SPC. For example, the anode electrode AE may be electrically connected to the first power voltage node VDDN through one or more transistors included in the sub-pixel circuit SPC. The cathode electrode CE may be electrically connected to the second power voltage node VSSN. The light emitting element LD may emit light according to a current flowing from the anode electrode AE to the cathode electrode CE.

The sub-pixel circuit SPC may be electrically connected to an ith gate line GLi among the first to mth gate lines GL1 to GLm shown in FIG. 1 and a jth data line DLj among the first to nth data lines DL1 to DLn shown in FIG. 1. In response to a gate signal received through the ith gate line GLi, the sub-pixel circuit SPC may control the light emitting element LD to emit light according to a data signal received through the jth data line DLj. The sub-pixel circuit SPC may be further electrically connected to the pixel control lines PXCL shown in FIG. 1. The sub-pixel circuit SPC may control the light emitting element LD in further response to control signals received through the pixel control lines PXCL.

For these operations, the sub-pixel circuit SPC may include circuit elements, e.g., transistors and one or more capacitors.

The transistors of the sub-pixel circuit SPC may include P-type transistors and/or N-type transistors. The transistors of the sub-pixel circuit SPC may include a Metal Oxide Silicon Field Effect Transistor (MOSFET). The transistors of the sub-pixel circuit SPC may include an amorphous silicon semiconductor, a monocrystalline silicon semiconductor, polycrystalline silicon semiconductor, an oxide semiconductor, and the like.

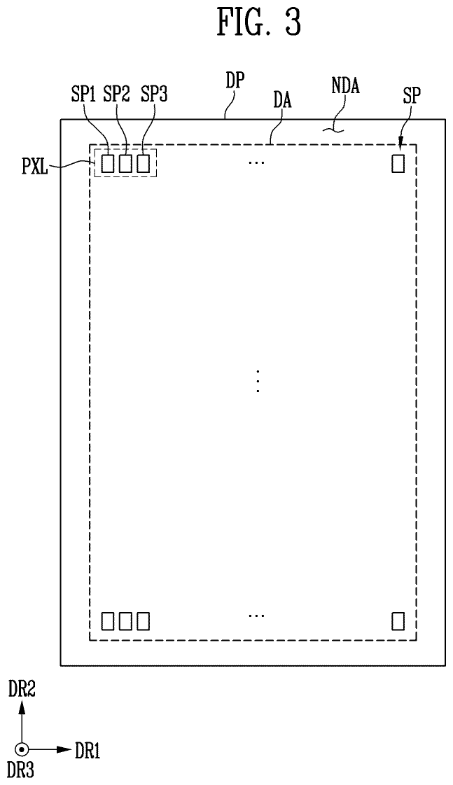

FIG. 3 is a schematic plan view illustrating an embodiment of the display panel shown in FIG. 1.

Referring to FIG. 3, a display panel DP may include a display area DA and a non-display area NDA. The display panel DP displays an image through the display area DA. The non-display area NDA may be disposed at the periphery of the display area DA. For example, the non-display area NDA may surround the display area DA.

The display panel DP may include multiple sub-pixels SP in the display area DA. The sub-pixels SP may be arranged in a first direction DR1 and a second direction DR2 intersecting the first direction DR1. For example, the sub-pixels SP may be arranged in a matrix form in the first direction DR1 and the second direction DR2. In another example, the sub-pixels SP may be arranged in a zigzag form in the first direction DR1 and the second direction DR2. The arrangement of the sub-pixels SP may vary in other embodiments. The first direction DR1 may be a row direction, and the second direction DR2 may be a column direction.

Two or more sub-pixels among multiple sub-pixels SP may constitute one pixel PXL. In FIG. 3, it is illustrated that the pixel PXL includes three sub-pixels SP1 to SP3. However, embodiments are not limited thereto. For example, the pixel PXL may include two sub-pixels. Hereinafter, for convenience of description, it is assumed that the pixel PXL includes first to third sub-pixels SP1 to SP3.

Each of the first to third sub-pixels SP1 to SP3 may generate light of one of various colors such as red, green, blue, cyan, magenta, and yellow. Hereinafter, for clear and simple description, it is assumed that the first sub-pixel SP1 generates light of a red color, the second sub-pixel SP2 generates light of a green color, and the third sub-pixel SP3 generates light of a blue color.

Each of the first to third sub-pixels SP1 to SP3 may include at least one light emitting element to generate light. Light emitting elements of the first to third sub-pixels SP1 to SP3 may generate light of the same color. For example, the light emitting elements of the first to third sub-pixels SP1 to SP3 may generate light of a blue color. In other embodiments, the light emitting elements of the first to third sub-pixels SP1 to SP3 may generate lights of different colors. For example, the light emitting elements of the first to third sub-pixels SP1 to SP3 may generate lights a red color, a green color, and a blue color, respectively.

Self-luminous display panels, such as a light emitting diode display panel (LED display panel) using a light emitting diode of micro scale or nano scale as a light emitting element and an organic light emitting display panel (OLED panel) using an organic light emitting diode as a light emitting element, may be used as the display panel DP.

A component for controlling the sub-pixels SP may be disposed in the non-display area NDA. Lines electrically connected to the sub-pixels SP, e.g., the first to mth gate lines GL1 to GLm, the first to nth data lines DL1 to DLn, the power lines PL, and the pixel control lines PXCL, which are shown in FIG. 1, may be disposed in the non-display area NDA.

At least one of the gate driver 120, the data driver 130, the voltage generator 140, and the controller 150, which are shown in FIG. 1, may be disposed in the non-display area NDA of the display panel DP. The gate driver 120 may be disposed in the non-display area NDA. The data driver 130, the voltage generator 140, and the controller 150 may be implemented into the driver integrated circuit DIC shown in FIG. 1, which is distinguished from the display panel DP, and the driver integrated circuit DIC may be electrically connected to the lines disposed in the non-display area NDA. In other embodiments, the gate driver 120, the data driver 130, the voltage generator 140, and the controller 150 may be implemented into one integrated circuit distinguished from the display panel DP.

The display area DA may have various shapes. The display area DA may have a closed-loop shape including linear sides and/or curved sides. For example, the display area DA may have shapes such as a polygon, a circle, a semicircle, and an ellipse.

The display panel DP may have a flat display surface. In other embodiments, the display panel DP may at least partially have a round display surface. The display panel DP may be bendable, foldable or rollable. The display panel DP and/or a substrate of the display panel DP may include materials having flexibility.

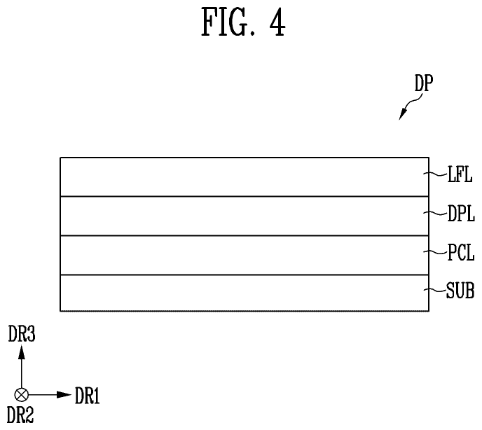

FIG. 4 is a schematic cross-sectional view illustrating an embodiment of the display panel shown in FIG. 3.

Referring to FIG. 4, a display panel DP may include a substrate SUB, and a pixel circuit layer PCL, a display element layer DPL, and a light functional layer LFL, which are sequentially stacked in a third direction DR3 intersecting the first and second directions DR1 and DR2 on the substrate SUB.

The substrate SUB may be made of an insulative material such as glass or resin. For example, the substrate SUB may include a glass substrate. In another example, the substrate SUB may include polyimide (PI) substrate. In still another example, the substrate SUB may include a silicon wafer substrate formed using a semiconductor process.

The substrate SUB may be made of a material having flexibility to be curvable or foldable, and have a single-layer structure or a multi-layer structure. For example, the material having flexibility may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be disposed on the substrate SUB. The pixel circuit layer PCL may include insulating layers, and semiconductor patterns and conductive patterns, which are disposed between the insulating layers. The conductive patterns of the pixel circuit layer PCL may serve as circuit elements, lines, and the like.

The circuit elements of the pixel circuit layer PCL may constitute a sub-pixel circuit SPC of each of the sub-pixels SP shown in FIG. 3. In other words, the circuit elements of the pixel circuit layer PCL may be provided as transistors and one or more capacitors of the sub-pixel circuit SPC.

The lines of the pixel circuit layer PCL may include lines electrically connected to each of the sub-pixels SP. The lines of the pixel circuit layer PCL may include various signal lines and/or various voltage lines, which are necessary for driving the display element layer DPL.

The display element layer DPL may be disposed on the pixel circuit layer PCL. The display element layer DPL may include light emitting elements of the sub-pixels SP.

The light functional layer LFL may be disposed on the display element layer DPL. The light functional layer LFL may include light conversion patterns having color conversion particles and/or light scattering particles. For example, color conversion particles may include quantum dots. The quantum dots may change a wavelength (or color) of light emitted from the display element layer DPL. The light functional layer LFL may further include light scattering patterns having light scattering particles. The light conversion patterns and the light scattering patterns may be omitted.

The light functional layer LFL may further include a color filter layer including color filters. The color filter may allow light having a specific wavelength (or specific color) to be selectively transmitted therethrough. The color filter layer may be omitted.

A window for protecting an exposed surface (or top surface) of the display panel DP may be provided on the light functional layer LFL. The window may protect the display panel DP from external impact. The window may be bonded to the light functional layer LFL through an optically transparent adhesive (or cohesive) member. The window may have a multi-layer structure selected from a glass substrate, a plastic film, and a plastic substrate. This multi-layer structure may be formed through a continuous process or an adhesive process using an adhesive layer. The whole or a portion of the window may have flexibility.

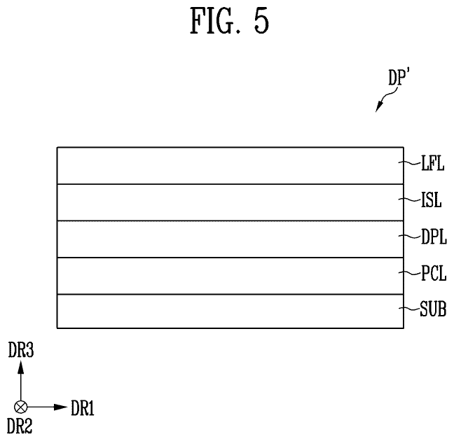

FIG. 5 is a schematic cross-sectional view illustrating another embodiment of the display panel shown in FIG. 3.

Referring to FIG. 5, a display panel DP′ may include a substrate SUB, a pixel circuit layer PCL, a display element layer DPL, an input sensing layer ISL, and a light functional layer LFL. The substrate SUB, the pixel circuit layer PCL, the display element layer DPL, and the light functional layer LFL may be similarly configured to the substrate SUB, the pixel circuit layer PCL, the display element layer DPL, and the light functional layer LFL, which are described with reference to FIG. 4, respectively. Hereinafter, overlapping descriptions will be omitted.

The input sensing layer ISL may sense a user input with respect to a top surface (or display surface) of the display panel DP′. The input sensing layer ISL may include components suitable for sensing an external object such as a hand of a user or a pen. For example, the input sensing layer ISL may include touch electrodes.

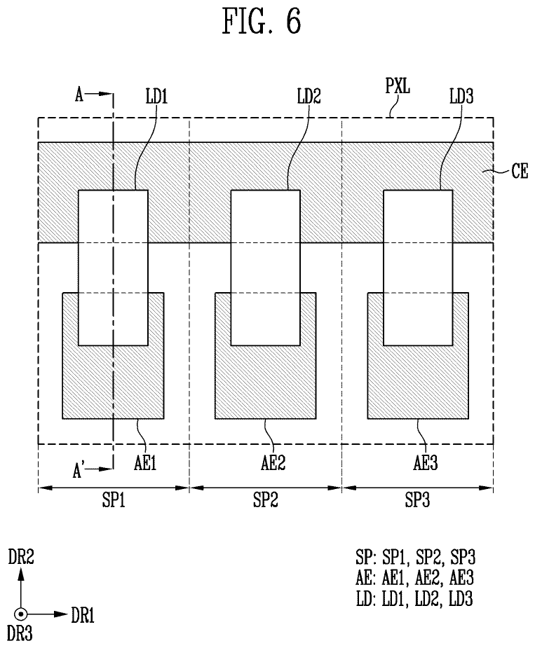

FIG. 6 is a schematic plan view illustrating an embodiment of any one of the pixels shown in FIG. 3.

Referring to FIG. 6, a pixel PXL may include first to third sub-pixels SP1 to SP3. The first to third sub-pixels SP1 to SP3 may be arranged in the first direction DR1. However, the arrangement of the pixel PXL is not limited thereto, and may be variously changed in other embodiments. For example, the first to third sub-pixels SP1 to SP3 may be arranged in zigzag.

First to third anode electrodes AE1 to AE3 may be disposed in the first to third sub-pixels SP1 to SP3, respectively. The first anode electrode AE1 may be provided as an anode electrode AE (see FIG. 2) electrically connected to a sub-pixel circuit SPC (see FIG. 2) of the first sub-pixel SP1. The second anode electrode AE2 may be provided as an anode electrode AE electrically connected to a sub-pixel circuit SPC of the second sub-pixel SP2. The third anode electrode AE3 may be provided as an anode electrode AE electrically connected to a sub-pixel circuit SPC of the third sub-pixel SP3.

A cathode electrode CE may be spaced apart from the first to third anode electrodes AE1 to AE3. The cathode electrode CE may be disposed at the same height as the first to third anode electrodes AE1 to AE3. The cathode electrode CE may be spaced apart from the first to third anode electrodes AE1 to AE3 in the second direction DR2. The cathode electrode CE may extend in the first direction DR1 to be used as a common electrode of the pixel PXL and other pixels adjacent to the pixel PXL. Although not shown in the drawing, the cathode electrode CE may extend in the second direction DR2 in addition to the first direction DR1 to be used as a common electrode of all the sub-pixels SP shown in FIG. 3. As such, the cathode electrode CE may have various shapes. The first to third anode electrodes AE1 to AE3 and the cathode electrode CE may include the same conductive material.

First to third light emitting elements LD1 to LD3 may be disposed on the first to third anode electrodes AE1 to AE3 and the cathode electrode CE. The first light emitting element LD1 may be electrically connected to the first anode electrode AE1 and the cathode electrode CE. The first light emitting element LD1 may be provided as a light emitting element LD (see FIG. 2) electrically connected to the sub-pixel circuit SPC of the first sub-pixel SP1. The second light emitting element LD2 may be electrically connected to the second anode electrode AE2 and the cathode electrode CE. The second light emitting element LD2 may be provided as a light emitting element LD electrically connected to the sub-pixel circuit SPC of the second sub-pixel SP2. The third light emitting element LD3 may be electrically connected to the third anode electrode AE3 and the cathode electrode CE. The third light emitting element LD3 may be provided as a light emitting element LD electrically connected to the sub-pixel circuit SPC of the third sub-pixel SP3.

The first light emitting element LD1, the second light emitting element LD2, and the third light emitting element LD3 may be inorganic light emitting diodes including an inorganic light emitting material. However, embodiments are not limited thereto. For example, organic light emitting diodes may be used.

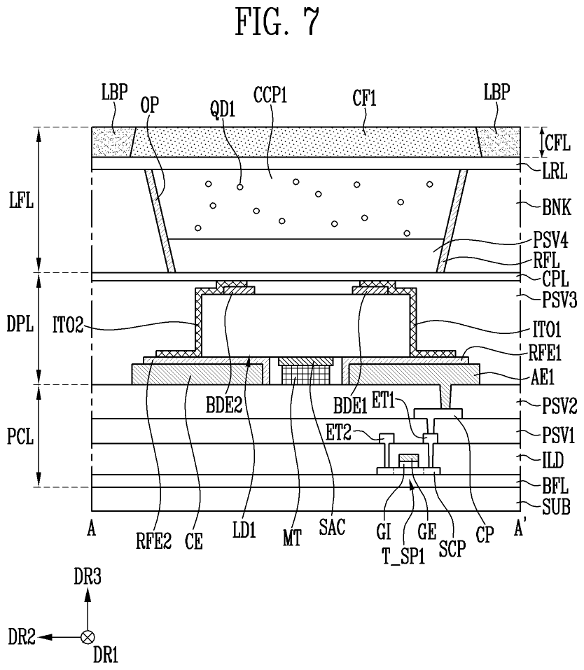

FIG. 7 is a schematic cross-sectional view illustrating an embodiment of the disclosure, which is taken along line A-A′ shown in FIG. 6.

Referring to FIGS. 6 and 7, a pixel circuit layer PCL, a display element layer DPL, and a light functional layer LFL may be sequentially disposed on a substrate SUB in the third direction DR3 (e.g., thickness direction).

Each of sub-pixel circuits corresponding to each of the first to third sub-pixels SP1 to SP3 may be disposed in the pixel circuit layer PCL. As described with reference to FIG. 2, the sub-pixel circuit SPC (see FIG. 2) of each of the first to third sub-pixels SP1 to SP3 may include transistors and one or more capacitors. Semiconductor patterns and conductive patterns of the pixel circuit layer PCL may serve as the transistors and the capacitors of the sub-pixel circuit SPC. The conductive patterns of the pixel circuit layer PCL may further serve as lines, e.g., the first to mth gate lines GL1 to GLm, the first to nth data lines DL1 to DLn, the power lines PL, and the pixel control lines PXCL, which are shown in FIG. 1.

The pixel circuit layer PCL may include a buffer layer BFL, at least one interlayer insulating layer ILD, a first passivation layer PSV1, and a second passivation layer PSV2.

The buffer layer BFL may be disposed on one surface of the substrate SUB. The buffer layer BFL may prevent an impurity from being diffused into circuit elements and lines, which are included in the pixel circuit layer PCL. The buffer layer BFL may include an inorganic insulating layer including an inorganic material. The buffer layer BFL may include at least one of silicon nitride (SiNₓ), silicon oxide (SiOₓ), silicon oxynitride (SiOₓN_{y}), and a metal oxide such as aluminum oxide (AlOₓ). The buffer layer BFL may be provided as a single layer or a multi-layer. In case that the buffer layer BFL is provided as the multi-layer, layers of the multi-layer may be formed of the same material or be formed of different materials.

One or more barrier layers may be disposed between the substrate SUB and the buffer layer BFL. Each of the barrier layers may include polyimide.

A transistor T_SP1 may be disposed on the buffer layer BFL. The transistor T_SP1 may be any one of the transistors of the sub-pixel circuit SPC included in the first sub-pixel SP1. For example, the transistor T_SP1 may be understood as a transistor electrically connected to the first anode electrode AE1 among the transistors of the sub-pixel circuit SPC.

The transistor T_SP1 may include a semiconductor pattern SCP, a gate electrode GE, a first terminal ET1, and a second terminal ET2. The first terminal ET1 may be any one of a source electrode and a drain electrode, and the second terminal ET2 may be another of the source electrode and the drain electrode. For example, the first terminal ET1 may be the source electrode, and the second terminal ET2 may be the drain electrode.

The semiconductor pattern SCP may be disposed on the buffer layer BFL. The semiconductor pattern SCP may include a first contact region in contact with the first terminal ET1 and a second contact region in contact with the second terminal ET2. A region between the first contact region and the second contact region may be a channel region. The channel region may overlap the gate electrode GE of the transistor T_SP1 in the third direction DR3. The channel region is a semiconductor pattern undoped with an impurity, and may be an intrinsic semiconductor. Each of the first contact region and the second contact region may be a semiconductor pattern doped with the impurity. For example, a p-type impurity may be used as the impurity, but embodiments are not limited thereto.

The semiconductor pattern SCP may include any one of various types of semiconductors, e.g., any one of an amorphous silicon semiconductor, a monocrystalline silicon semiconductor, a polycrystalline silicon semiconductor, a low temperature poly-silicon semiconductor, and an oxide semiconductor.

The sequentially stacked interlayer insulating layers ILD may be disposed over the semiconductor pattern SCP. The interlayer insulating layers ILD may be inorganic insulating layers including an inorganic material. For example, each of the interlayer insulating layers ILD may include at least one of silicon nitride (SiNₓ), silicon oxide (SiOₓ), silicon oxynitride (SiOₓN_{y}), and a metal oxide such as aluminum oxide (AlOₓ). However, the interlayer insulating layers ILD are not limited thereto. For example, any one of the interlayer insulating layers ILD may include an organic insulating layer including an organic material.

The interlayer insulating layers ILD may electrically separate the conductive patterns and/or the semiconductor patterns which are disposed between the interlayer insulating layers ILD. For example, the interlayer insulating layers ILD may include a gate insulating layer GI disposed on the semiconductor pattern SCP. The gate insulating layer GI may be disposed between the semiconductor pattern SCP and the gate electrode GE such that the gate electrode GE is spaced apart from the semiconductor pattern SCP with respect to the gate insulating layer GI. The gate insulating layer GI may be entirely provided on the semiconductor pattern SCP and the buffer layer BFL to cover the semiconductor pattern SCP and the buffer layer BFL. As the number of layers required to form the conductive patterns and/or the semiconductor patterns increases, the number of interlayer insulating layers ILD may increase.

The gate electrode GE may be disposed on the gate insulating layer GI. The gate electrode GE may overlap the channel region of the semiconductor pattern SCP in the third direction DR3. The gate electrode GE may be provided as a single layer including at least one material among copper (Cu), molybdenum (Mo), tungsten (W), aluminum neodymium (AlNd), titanium (Ti), aluminum (Al), and silver (Ag). The gate electrode GE may be provided as a multi-layer including at least one material among molybdenum (Mo), titanium (Ti), copper (Cu), aluminum (Al), and silver (Ag), which are low resistance materials.

The first and second terminals ET1 and ET2 may be disposed on the interlayer insulating layers ILD. The first and second terminals ET1 and ET2 may be in contact with the semiconductor pattern SCP through contact holes penetrating the interlayer insulating layers ILD. The first and second terminals ET1 and ET2 may be in contact with the first and second contact regions of the semiconductor pattern SCP, respectively. Each of the first and second terminals ET1 and ET2 may include at least one material among copper (Cu), molybdenum (Mo), tungsten (W), aluminum neodymium (AlNd), titanium (Ti), aluminum (Al), and silver (Ag).

Although the first and second terminals ET1 and ET2 are illustrated as individual electrodes electrically connected to the semiconductor pattern SCP, embodiments are not limited thereto. The first terminal ET1 may be the first contact region adjacent to one side of the channel region of the semiconductor pattern SCP, and the second terminal ET2 may be the second contact region adjacent to another side of the channel region of the semiconductor pattern SCP. The first terminal ET1 may be electrically connected to a light emitting element LD through a connection means such as a bridge electrode, which is disposed on at least one of the interlayer insulating layers ILD.

The transistor T_SP1 may be a low temperature poly-silicon transistor. However, embodiments are not limited thereto. For example, the transistor T_SP1 may be an oxide semiconductor transistor. The sub-pixel circuit of the first sub-pixel SP1 may include different types of transistors. For example, the transistor T_SP1 may be a low temperature poly-silicon transistor, and another transistor of the first sub-pixel SP1 may be an oxide semiconductor transistor. An oxide semiconductor of the corresponding oxide semiconductor transistor may be disposed on any one of the interlayer insulating layers ILD instead of an insulating layer on which the semiconductor pattern SCP of the transistor T_SP1 is disposed.

A case where the transistor T_SP1 is a transistor having a top gate structure is described as an example. However, embodiments are not limited thereto. For example, the transistor T_SP1 may be a transistor having a bottom gate structure. The structure of the transistor T_SP1 may be variously changed.

At least some of various lines of the display panel DP and/or the display device DD may be further disposed on the interlayer insulating layers ILD.

The first passivation layer PSV1 may be disposed over the interlayer insulating layers ILD and the first and second terminals ET1 and ET2. A passivation layer may be designated as a protective layer or a via layer. The first passivation layer PSV1 may protect components disposed thereunder, and provide a flat top surface.

A connection pattern CP may be disposed on the first passivation layer PSV1. The connection pattern CP may be electrically connected to the first terminal ET1 of the transistor T_SP1 while penetrating the first passivation layer PSV1. The connection pattern CP may include at least one material among copper (Cu), molybdenum (Mo), tungsten (W), aluminum neodymium (AlNd), titanium (Ti), aluminum (Al), and silver (Ag).

At least some of various lines of the display panel DP and/or the display device DD may be further disposed on the first passivation layer PSV1.

The second passivation layer PSV2 may be disposed over the connection pattern CP and the first passivation layer PSV1. The second passivation layer PSV2 may protect components disposed thereunder, and provide a flat top surface.

Each of the first and second passivation layers PSV1 and PSV2 may include an inorganic insulating layer including an inorganic material and/or an organic insulating layer including an organic material. The inorganic insulating layer may include, for example, at least one of silicon oxide (SiOₓ), silicon nitride (SiNₓ), silicon oxynitride (SiOₓN_{y}), and a metal oxide such as aluminum oxide (AlOₓ). The organic insulating layer may include, for example, at least one of acrylic resin, epoxy resin, phenolic resin, polyamide resin, polyimide resin, unsaturated polyester resin, poly-phenylene ether resin, poly-phenylene sulfide resin, and benzocyclobutene resin.

The first and second passivation layers PSV1 and PSV2 may include the same material as any one of the interlayer insulating layers ILD, but embodiments are not limited thereto. Each of the first and second passivation layers PSV1 and PSV2 may be provided as a single layer, but be provided as a multi-layer.

The display element layer DPL may be disposed on the second passivation layer PSV2. The display element layer DPL may include a first anode electrode AE1, a cathode electrode CE, first and second reflective electrodes RFE1 and RFE2, a first light emitting element LD1, a third passivation layer PSV3, and a capping layer CPL.

The first anode electrode AE1 and the cathode electrode CE may be disposed on the pixel circuit layer PCL. For example, the first anode electrode AE1 and the cathode electrode CE may be disposed on the second passivation layer PSV2.

The first anode electrode AE1 may be electrically connected to the connection pattern CP through a contact hole penetrating the second passivation layer PSV2. As such, the first anode electrode AE1 may be electrically connected to the transistor T_SP1.

The cathode electrode CE may be spaced apart from the first anode electrode AE1 in the second direction DR2. The cathode electrode CE may be electrically connected to the second power voltage node VSSN shown in FIG. 2. Accordingly, the second power voltage applied to the second power voltage node VSSN may be transferred to the cathode electrode CE.

The first anode electrode AE1 and the cathode electrode CE may be disposed in the same layer, and include the same conductive material. In other embodiments, the first anode electrode AE1 and the cathode electrode CE may include a transparent conductive material. For example, the transparent conductive material may include at least one selected from the group consisting of silver nano wire (AgNW), Indium Tin Oxide (ITO), Indium Zinc Oxide (IZO), Indium Gallium Zinc Oxide (IGZO), Antimony Zinc Oxide (AZO), Indium Tin Zinc Oxide (ITZO), Zinc Oxide (ZnO), Tin Oxide (SnO₂), carbon nano tube, and graphene. However, the disclosure is not limited thereto.

The first reflective electrode RFE1 may be disposed on the first anode electrode AE1. The first reflective electrode RFE1 may be disposed on a side surface of the first anode electrode AE1.

The second reflective electrode RFE2 may be disposed on the cathode electrode CE. The second reflective electrode RFE2 may be disposed on a side surface of the cathode electrode CE.

The first and second reflective electrodes RFE1 and RFE2 may include conductive materials suitable for reflecting light. Accordingly, the light output efficiency of the first light emitting element LD1 may be improved. The first and second reflective electrodes RFE1 and RFE2 may include the same reflective conductive material. The first and second reflective electrodes RFE1 and RFE2 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

A first bonding metal MT may be disposed on the second passivation layer PSV2. In a cross-sectional view, the first bonding metal MT may be disposed between the first anode electrode AE1 and the cathode electrode CE in the second direction DR2. The first bonding metal MT may be disposed in a space in which the cathode electrode CE and the first anode electrode AE1 are spaced apart from each other in the second direction DR2. The first bonding metal MT, the cathode electrode CE, and the first anode electrode AE1 may be spaced apart from each other in the second direction DR2. The first bonding metal MT may be spaced apart from the first and second reflective electrodes RFE1 and RFE2.

The first anode electrode AE1, the cathode electrode CE, and the first bonding metal MT may be disposed in the same layer. For example, the first anode electrode AE1, the cathode electrode CE, and the first bonding metal MT may be disposed on the second passivation layer PSV2.

The first bonding metal MT may include a metal material. The first bonding metal MT may include copper (Cu). The first bonding metal MT may fix the first light emitting element LD1 not to move.

The first light emitting element LD1 may include first and second element electrodes BDE1 and BDE2 facing in the same direction. In FIG. 7, it is illustrated that the first and second element electrodes BDE1 and BDE2 face in the third direction DR3. However, the disclosure is not limited thereto, and the first and second element electrodes BDE1 and BDE2 may face in the opposite direction of the third direction DR3. For example, the first and second element electrodes BDE1 and BDE2 may be disposed on a bottom surface and side surfaces of the first light emitting element LD1. Accordingly, a bottom surface of the element electrode BDE1 may be in contact with the first reflective electrode REF1, and a bottom surface of the second element electrode BDE2 may be in contact with the second reflective electrode RFE2.

The first and second element electrodes BDE1 and BDE2 may be spaced apart from each other in the second direction DR2. The first element electrode BDE1 may be disposed adjacent to the first anode electrode AE1, and the second element electrode BDE2 may be disposed adjacent to the cathode electrode CE.

The first and second element electrodes BDE1 and BDE2 may include conductive materials suitable for reflecting light. Accordingly, the light output efficiency of the first light emitting element LD1 may be improved. The first and second element electrodes BDE1 and BDE2 may include the same reflective conductive material.

The first light emitting element LD1 may include a second bonding metal SAC. The second bonding metal SAC may face in the opposite direction of the third direction DR3. For example, in a cross-sectional view, the second bonding metal SAC may be located at the center of the bottom surface of the first light emitting element LD1.

In embodiments, in case that the first and second element electrodes BDE1 and BDE2 are disposed on the bottom surface and the side surfaces of the first light emitting element LD1, the second bonding metal SAC may be disposed between the first and second element electrodes BDE1 and BDE2. The second bonding metal SAC may be spaced apart from the first and second element electrodes BDE1 and BDE2.

The second bonding metal SAC may include a metal material. The second bonding metal SAC may be made of a combination of tin (Sn), silver (Ag), and copper (Cu).

The second bonding metal SAC may be disposed on the first bonding metal MT. For example, in a plan view, the first bonding metal MT and the second bonding metal SAC may overlap each other in the third direction DR3.

The second bonding metal SAC may be disposed on the first bonding metal MT, and an Inter Metallic Compound (IMC) ally may be formed in an area in which the first bonding metal MT and the second bonding metal SAC are in contact with each other by irradiating laser. Accordingly, the first light emitting element LD1 can be disposed on the first anode electrode AE1 and the cathode electrode CE without an adhesive layer, and be fixed by the IMC alloy.

As the separate adhesive layer is not used, problems of a defect caused by a foreign matter sticking to the adhesive layer and deterioration of the adhesion of the adhesive layer may be solved.

An adhesive layer between the first and second reflective electrodes RFE1 and RFE2 and the first light emitting element LD1 is removed, light leakage due to a gap caused by the adhesive layer may be solved.

The second bonding metal SAC may serve as a reflective layer. As the second bonding metal SAC is used as the reflective layer, light of the first light emitting element LD1 is reflected upwardly (e.g., in the third direction DR3) so that the luminance of the display device DD may be increased.

In case that the first light emitting element LD1 is fixed using an adhesive layer, it is difficult to perform a repair process after the adhesive layer is cured. On the other hand, in case that the first light emitting element LD1 is fixed by forming the IMC alloy, using the first and second bonding metals MT and SAC, the repair process may be performed by melting the IMC alloy.

A first transparent electrode ITO1 may directly electrically connect the first reflective electrode RFE1 to the first element electrode BDE1. Accordingly, the first element electrode BDE1 may be electrically connected to the first anode electrode AE1 through the first transparent electrode ITO1 and the first reflective electrode RFE1.

The first transparent electrode ITO1 may be disposed on an exposed portion of the first element electrode BDE1, an exposed portion of the first light emitting element LD1, and an exposed portion of the first reflective electrode RFE1. For example, the first transparent electrode ITO1 may be disposed along a side surface of the first light emitting element LD1, which is adjacent to the first anode electrode AE1. The first transparent electrode ITO1 may overlap the first element electrode BDE1 in a plan view.

A second transparent electrode ITO2 may directly electrically connect the second reflective electrode RFE2 to the second element electrode BDE2. Accordingly, the second element electrode BDE2 may be electrically connected to the cathode electrode CE through the second transparent electrode ITO2 and the second reflective electrode RFE2.

The second transparent electrode ITO2 may be disposed on an exposed portion of the second element electrode BDE2, an exposed portion of the first light emitting element LD1, and an exposed portion of the second reflective electrode RFE2. For example, the second transparent electrode ITO2 may be disposed along a side surface of the first light emitting element LD1, which is adjacent to the cathode electrode CE. The second transparent electrode ITO2 may overlap the second element electrode BDE2 in a plan view.

The first and second transparent electrodes ITO1 and ITO2 may be formed substantially transparent or translucent to satisfy a predetermined light transmittance. The first transparent electrode ITO1 and the second transparent electrode ITO2 may be disposed in the same display element layer DPL, and include the same transparent conductive material. The first and second transparent electrodes ITO1 and ITO2 may include at least one of various transparent conductive materials such as indium tin oxide (ITO), indium zinc oxide (IZO), zinc oxide (ZnO), indium gallium zinc oxide (IGZO), and indium tin zinc oxide (ITZO). However, the material of the first and second transparent electrodes ITO1 and ITO2 is not limited thereto.

The third passivation layer PSV3 may be disposed over the first and second transparent electrodes ITO1 and ITO2. The third passivation layer PSV3 may protect components disposed thereunder, and provide a flat top surface. The third passivation layer PSV3 may include the same material as any one of the first and second passivation layers PSV1 and PSV2, but embodiments are not limited thereto.

In FIG. 7, it is illustrated that the first light emitting element LD1 does not protrude to the light functional layer LFL. However, the disclosure is not limited thereto, and the first light emitting element LD1 may protrude to the light functional layer LFL. The first light emitting element LD1 may be at least partially located in an opening OP of a bank BNK. Accordingly, light emitted from the first light emitting element LD1 may be provided to the light functional layer LFL at a relatively high ratio.

The capping layer CPL may be disposed on the third passivation layer PSV3. The capping layer CPL may protect components disposed under the capping layer CPL such as the first light emitting element LD1, from external moisture, humidity, and the like. The capping layer CPL may not be disposed on a top surface of the first light emitting element LD1. In other embodiments, the capping layer CPL may entirely cover the first light emitting element LD1 and the third passivation layer PSV3. The capping layer CPL may include at least one of silicon nitride (SiNₓ), silicon oxide (SiOₓ), silicon oxynitride (SiOₓN_{y}), and a metal oxide such as aluminum oxide (AlOₓ). However, the material of the capping layer CPL is not limited thereto.

In the above, the pixel circuit layer PCL and the display element layer DPL of the first sub-pixel SP1 have been described. Each of the second and third sub-pixels SP2 and SP3 shown in FIG. 6 may also be similarly configured to the first sub-pixel SP1 within a range in which it is not differently described herein.

The light functional layer LFL may be disposed on the capping layer CPL. The light functional layer LFL may include the BNK, a reflective layer RFL, a fourth passivation layer PSV4, a first light conversion pattern CCP1, a low refractive layer LRL, and a color filter layer CFL.

The bank BNK may be disposed on the capping layer CPL. The bank BNK may include a light blocking material to prevent light mixture between adjacent sub-pixels. The bank BNK may include an organic material. For example, the bank BNK may include an organic insulating material such as acrylic resin, epoxy resin, phenolic resin, polyamide resin, or polyimide resin.

The reflective layer RFL may be disposed on side surfaces of the bank BNK which are adjacent to the opening OP. The reflective layer RFL may reflect incident light, and accordingly, light output efficiency may be improved. The reflective layer RFL may include a material suitable for reflecting light. The reflective layer RFL may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom. However, embodiments are not limited thereto.

On the capping layer CPL, the fourth passivation layer PSV4 may be disposed in the opening OP. The fourth passivation layer PSV4 may protect components disposed thereunder, and provide a flat surface. The fourth passivation layer PSV4 may include the same material as any one of the first to third passivation layers PSV1, PSV2, and PSV3, but embodiments are not limited thereto.

On the fourth passivation layer PSV4, the first light conversion pattern CCP1 may be disposed in the opening OP.

The first light conversion pattern CCP1 may include color conversion particles and/or light scattering particles. The color conversion particles may convert incident light into light of another color by changing a wavelength of the incident light. The color conversion particles may scatter incident light. The color conversion particles may be quantum dots. The light scattering particles may scatter incident light.

The first sub-pixel SP1 may be a red sub-pixel. In case that the first light emitting element LD1 emits light of a blue color, the first light conversion pattern CCP1 may include first color conversion particles QD1 to convert light of the blue color into light of a red color. In case that the first light emitting element LD1 emits light of the red color, the first light conversion pattern CCP1 may include light scattering particles. As such, the particles included in the first light conversion pattern CCP1 may be variously changed according to the first light emitting element LD1.

The low refractive layer LRL may be disposed on the bank BNK, the reflective layer RFL, and the first light conversion pattern CCP1. The low refractive layer LRL may have a refractive index lower than a refractive index of the first light conversion pattern CCP1. A first color filter CF1 may have a refractive index higher than the refractive index of the low refractive layer LRL. However, embodiments are not limited thereto, and the first color filter CF1 may have a refractive index lower than or equal to the refractive index of the low refractive layer LRL. The low refractive layer LRL may refract or totally reflect light according to an incident angle of the corresponding light. For example, the low refractive layer LRL may again provide light passing through the first light conversion pattern CCP1 to the first light conversion pattern CCP1. Accordingly, the light conversion efficiency of the first light conversion pattern CCP1 can be improved.

The color filter layer CFL may be disposed on the low refractive layer LRL. The color filter layer CFL may include the first color filter CF1 and light blocking patterns LBP. The first color filter CF1 overlaps with the first light conversion pattern CCP1. The first color filter CF1 may allow light in a desired wavelength range to be selectively transmitted therethrough. In case that the first sub-pixel SP1 is a red sub-pixel, the first color filter CF1 may include a red color filter. The light blocking patterns LBP may include at least one of various kinds of light blocking materials.

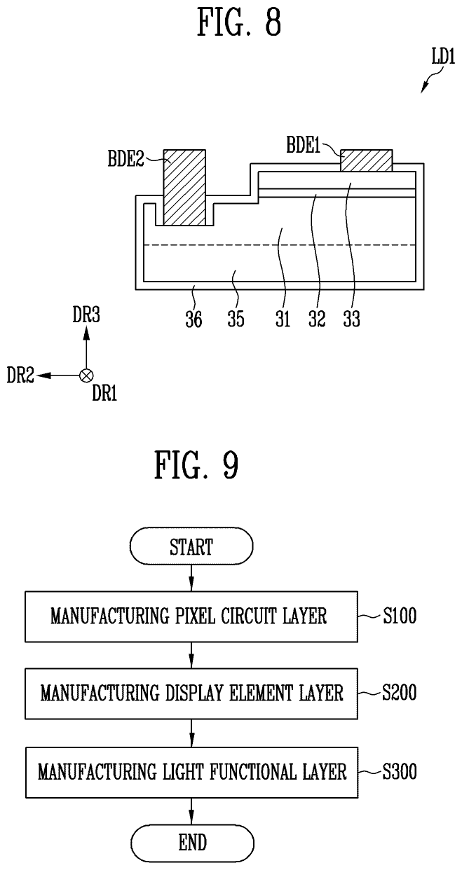

FIG. 8 is a schematic cross-sectional view illustrating the first light emitting element shown in FIG. 7.

Referring to FIGS. 7 and 8, the first light emitting element LD1 may include a first semiconductor layer 31, an active layer 32, a second semiconductor layer 33, and an auxiliary layer 35.

The first light emitting element LD1 may include a light emitting stack structure in which the auxiliary layer 35, the first semiconductor layer 31, the active layer 32, and the second semiconductor layer 33 are sequentially stacked in the third direction DR3.

The first light emitting element LD1 includes first and second elements electrodes BDE1 and BDE2 facing in the same direction (e.g., the third direction DR3). The first element electrode BDE1 may be electrically connected to the second semiconductor layer 33. The second element electrode BDE2 may be electrically connected to the first semiconductor layer 31 exposed as the second semiconductor layer 33 and the active layer 32 are exposed.

The first semiconductor layer 31 may provide electrons to the active layer 32. The first semiconductor layer 31 may include, for example, at least one n-type semiconductor layer. For example, the first semiconductor layer 31 may include any one semiconductor material among gallium nitride (GaN), aluminum gallium nitride (AlGaN), indium gallium nitride (InGaN), aluminum nitride (AlN), and indium nitride (InN), and be an n-type semiconductor layer doped with a first conductive dopant (or n-type dopant) such as silicon (Si), germanium (Ge) or tin (Sn). However, the material constituting the first semiconductor layer 31 is not limited thereto. Various materials may constitute the first semiconductor layer 31. The first semiconductor layer 31 may include a gallium nitride (GaN) semiconductor material doped with the first conductive dopant (or n-type dopant). In other embodiments, the first semiconductor layer 31 along with the auxiliary layer 35 may constitute an n-type semiconductor layer.

The active layer 32 may be disposed on the first semiconductor layer 31, and may be an area in which electrons and holes are recombined. As electrons and holes are recombined in the active layer 32, light may be generated, which has a level changed to a low energy level and has a wavelength corresponding to the low energy level. The active layer 32 may be formed in a single quantum well structure or a multi-quantum well structure. In case that the active layer 32 is formed in the multi-quantum well structure, a unit including a barrier layer, a strain reinforcing layer, and a well layer may be repeatedly stacked, to form the active layer 32. However, embodiments of the active layer 32 are not limited thereto.

The second semiconductor layer 33 may be disposed on the active layer 32 and provide holes to the active layer 32. The second semiconductor layer 33 may include a semiconductor layer of which type is different from the type of the first semiconductor layer 31. In an example, the second semiconductor layer 33 may include at least one p-type semiconductor layer. For example, the second semiconductor layer 33 may include any one semiconductor material among gallium nitride (GaN), aluminum gallium nitride (AlGaN), indium gallium nitride (InGaN), aluminum nitride (AlN), and indium nitride (InN), and be a p-type semiconductor layer doped with a second conductive dopant (or p-type dopant) such as magnesium (Mg), zinc (Zn), calcium (Ca), strontium (Sr) or barium (Ba). However, the material constituting the second semiconductor layer 33 is not limited thereto. Various materials may constitute the second semiconductor layer 33. The second semiconductor layer 33 may include a gallium nitride (GaN) semiconductor material doped with the second conductive dopant (or p-type dopant).

The auxiliary layer 35 may include a gallium nitride (GaN) semiconductor material undoped with an impurity. The auxiliary layer 35 along with the first semiconductor layer 31 may constitute an n-type semiconductor layer.

The first element electrode BDE1 may be electrically connected to the second semiconductor layer 33. The second element electrode BDE2 may be electrically connected to the first semiconductor layer 31.

The first light emitting element LD1 may further include an insulative film 36 covering an outer circumferential surface of the light emitting stack structure. The insulative film 36 may prevent an electrical short circuit which may occur while the active layer 32 is in contact with another conductive material except the first and second semiconductor layers 31 and 33. The insulative film 36 may include a transparent insulating material. The insulative film 36 may expose top surfaces of the first and second element electrodes BDE1 and BDE2.

In the above, the first light emitting element LD1 of the first sub-pixel SP1 have been described. Each of the second and third sub-pixels SP2 and SP3 shown in FIG. 6 may also include a light emitting element configured similarly to the first light emitting element LD1 within a range in which it is not differently described herein.

Hereinafter, a method of manufacturing a display device DD in accordance with an embodiment of the disclosure will be described with reference to FIGS. 9 to 14. In FIGS. 9 to 14, descriptions of portions overlapping with the above-described portions will be simplified or will not be repeated.

FIG. 9 is a schematic flowchart illustrating a method of manufacturing a display device in accordance with an embodiment of the disclosure.

Referring to FIG. 9, the method of manufacturing the display device DD in accordance with the embodiment of the disclosure may include a step S100 of manufacturing a pixel circuit layer, a step S200 of manufacturing a display element layer, and a step S300 of manufacturing a light functional layer.

Referring to FIGS. 7 and 9, in the step S100 of manufacturing the pixel circuit layer, a pixel circuit layer PCL may be disposed on a substrate SUB.

In other embodiments, a conductive layer or an insulating layer on the substrate SUB may be formed based on an ordinary (or standard) process for manufacturing a semiconductor device. For example, the conductive layer or the insulating layer on the substrate SUB may be formed through a photolithography process, be etched through various processes (wet etching, dry etching, and the like), and be deposited through various processes (sputtering, chemical vapor deposition, and the like). However, the disclosure is not limited thereto.

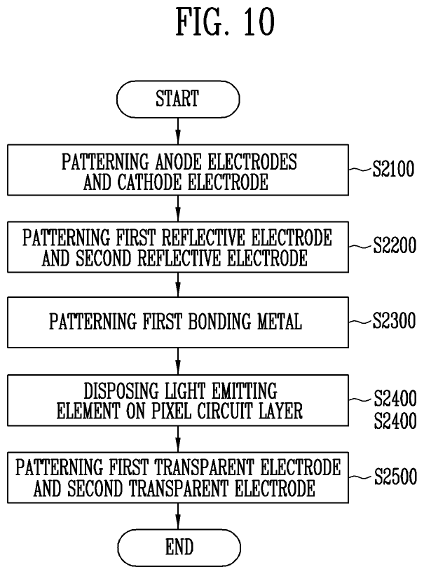

Referring to FIGS. 7 to 9, in the step S200 of manufacturing the display element layer, a first light emitting element LD1 may be disposed on the pixel circuit layer PCL. This will be described in more detail together with FIG. 10.

Referring to FIGS. 7 and 9, in the step S300 of manufacturing the light functional layer, a light functional layer LFL may be disposed on a display element layer DPL. In this step S300, layers for forming the light functional layer LFL may be sequentially formed on the display element layer DPL. For example, referring to FIG. 7, a bank BNK, a reflective layer RFL, a fourth passivation layer PSV4, a first light conversion pattern CCP1, a low refractive layer, and a color filter layer CFL may be formed on a capping layer CPL.

FIG. 10 is a schematic flowchart illustrating the step of manufacturing the display element layer in accordance with an embodiment of the disclosure.

Referring to FIGS. 9 and 10, the step S200 of manufacturing the display element layer may include a step S2100 of patterning anode electrodes and a cathode electrode, a step S2200 of patterning a first reflective electrode and a second reflective electrode, a step S2300 of patterning a first bonding metal, a step S2400 of disposing a light emitting element on the pixel circuit layer, and a step S2500 of patterning a first transparent electrode and a second transparent electrode.

Referring to FIG. 7, in the step S2100 of patterning the anode electrodes and the cathode electrode, a first anode electrode AE1 and a cathode electrode CE may be formed on the pixel circuit layer PCL (or the substrate SUB). In this step S2100, a second anode electrode and a third anode electrode may be formed.

In this step S2100, in case that the first anode electrode AE1 is formed, a contact hole penetrating a second passivation layer PSV2 may be formed. Accordingly, the first anode electrode AE1 may be electrically connected to a transistor T_SP1.

Referring to FIG. 7, in the step S2200 of patterning the first reflective electrode and the second reflective electrode, a first reflective electrode RFE1 may be formed on the first anode electrode AE1, and a second reflective electrode REF2 may be formed on the cathode electrode CE.

Referring to FIG. 7, in the step S2300 of patterning the first bonding metal, a first bonding metal MT may be formed on the pixel circuit layer PCL. The first bonding metal MT may be formed on the second passivation layer PSV2. In a cross-sectional view, the first bonding metal MT may be disposed between the first anode electrode AE1 and the cathode electrode CE. The first anode electrode AE1, the cathode electrode CE, and the first bonding metal MT may be spaced apart from each other.

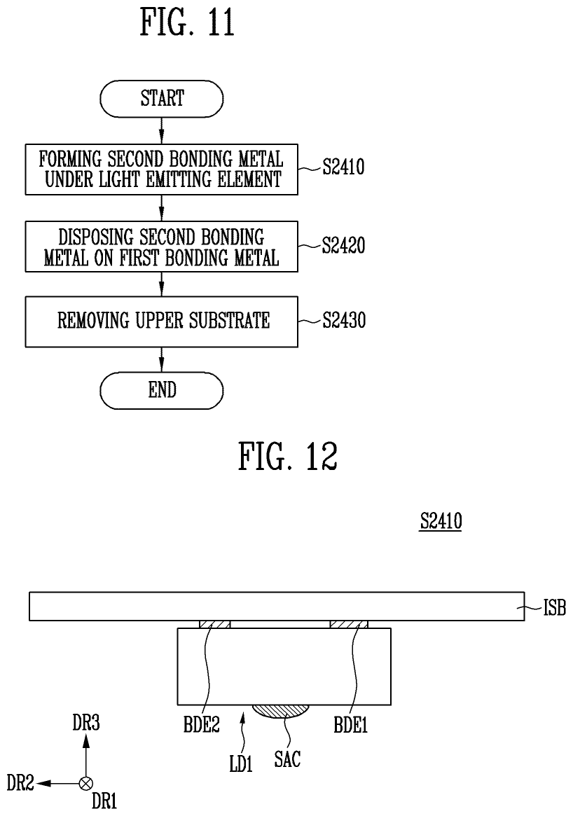

Referring to FIG. 7, in the step S2400 of disposing the light emitting element on the pixel circuit layer, a first light emitting element LD1 may be disposed on the first reflective electrode RFE1, the second reflective electrode RFE2, and the first bonding metal MT. This will be described in more detail together with FIGS. 11 to 14.

Referring to FIG. 7, in the step S2500 of patterning the first transparent electrode and the second transparent electrode, a first transparent electrode ITO1 may be disposed on an exposed portion of a first element electrode BDE1, an exposed portion of the first light emitting element LD1, and an exposed portion of the first reflective electrode RFE1, and a second transparent electrode ITO2 may be disposed on an exposed portion of a second element electrode BDE2, an exposed portion of the first light emitting element LD1, and an exposed portion of the second reflective electrode RFE2.

FIG. 11 is a schematic flowchart illustrating the step of disposing the light emitting element in accordance with an embodiment of the disclosure. FIGS. 12 to 14 are schematic sectional views illustrating process steps according to the step shown in FIG. 11. For convenience of descriptions, FIGS. 12 to 14 schematically illustrate an area corresponding to the sectional structure described above with reference to FIG. 7.

Referring to FIGS. 10 and 11, the step S2400 of disposing the light emitting element on the pixel circuit layer may include a step S2410 of forming a second bonding metal under the light emitting element, a step S2420 of disposing the second bonding metal on the first bonding metal, and a step S2430 of removing an upper substrate.

Referring to FIGS. 11 and 12, in the step S2410 of forming the second bonding metal under the light emitting element, a second bonding metal SAC may be formed under the first light emitting element LD1.

The second bonding metal SAC may be formed under the first light emitting element LD1 in a state in which the first light emitting element LD1 is disposed on an upper substrate ISB. Top surfaces of the first and second element electrodes BDE1 and BDE2 of the first light emitting element LD1 may be electrically connected to the upper substrate ISB. For example, the upper substrate ISB may be an interposer substrate.

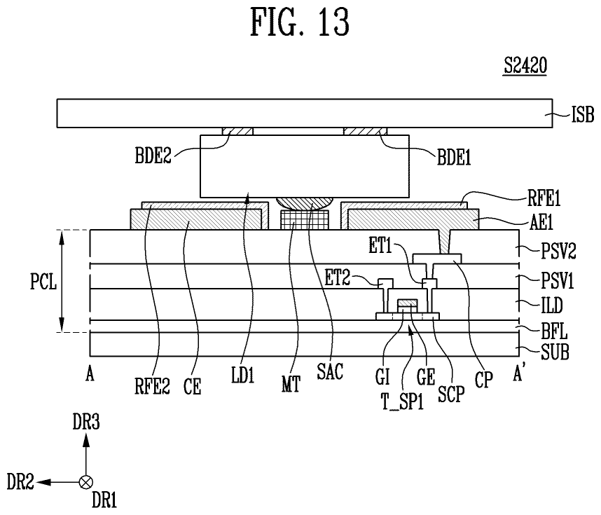

Referring to FIGS. 11 and 13, in the step S2420 of disposing the second bonding metal on the first bonding metal, the second bonding metal SAC may be disposed on the first bonding metal MT. In a plan view, the second bonding metal SAC and the first bonding metal MT may overlap each other.

The second bonding metal SAC may be disposed on the first bonding metal, and an Inter Metallic Compound (IMC) alloy may be formed by irradiating laser. Accordingly, the first light emitting element LD1 may be disposed on the first anode electrode AE1 and the cathode electrode CE without an adhesive layer, and be fixed by the IMC alloy.

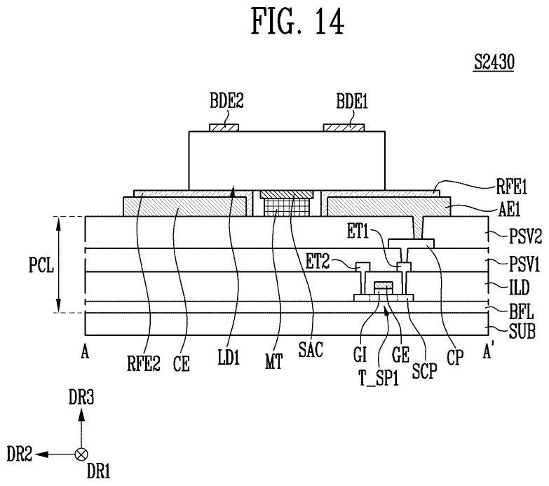

Referring to FIGS. 11 and 14, in the step S2430 of removing the upper substrate, the upper substrate ISB separated from the first light emitting element LD1 may be removed.

Laser for separating the upper substrate ISB from the first light emitting element LD1 and the laser for forming the IMC allow in the step S2420 may be the same process. Accordingly, the step S2420 may be performed using an existing process of separating the upper substrate ISB from the first light emitting element LD1. For example, an additional separation process for forming the IMC alloy may not exist.

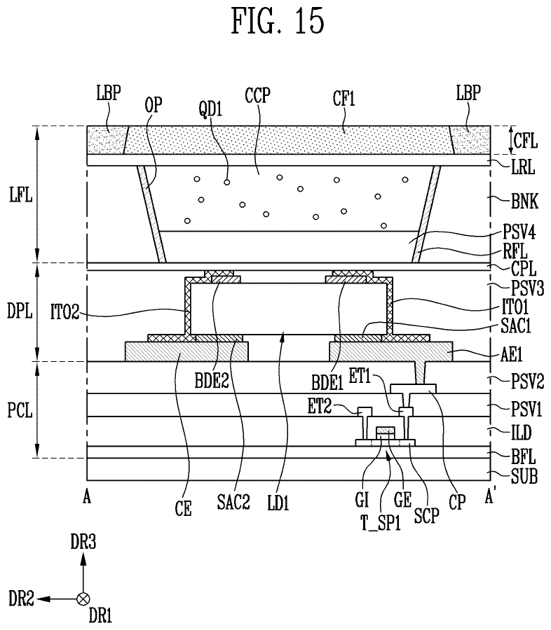

FIG. 15 is a schematic cross-sectional view illustrating another embodiment of the disclosure, which is taken along line A-A′ shown in FIG. 6.

Referring to FIGS. 6 and 15, a pixel circuit layer PCL, a display element layer DPL, and a light functional layer LFL may be sequentially disposed on a substrate SUB in the third direction DR3. The pixel circuit layer PCL, the display element layer DPL, and a light functional layer LFL, which are shown in FIG. 15, are similarly configured to the pixel circuit layer PCL, the display element layer DPL, and a light functional layer LFL, which are shown in FIG. 7, and therefore, overlapping descriptions will be omitted.

A first light emitting element LD1 may include first and second element electrodes BDE1 and BDE2 facing in the same direction.

The first and second element electrodes BDE1 and BDE2 may be spaced apart from each other in the second direction DR2. The first element electrode BDE1 may be disposed adjacent to a first anode electrode AE1, and the second element electrode BDE2 may be disposed adjacent to a cathode electrode CE.

The first light emitting element LD1 may include a first sub-bonding metal SAC1 and a second sub-bonding metal SAC2. The first sub-bonding metal SAC1 and the second sub-bonding metal SAC2 may face in the opposite direction of the third direction DR3. For example, in a cross-sectional view, the first sub-bonding metal SAC1 and the second sub-bonding metal SAC2 may be disposed on a bottom surface of the first light emitting element LD1.

In a plan view, the first sub-bonding metal SAC1 may overlap the first anode electrode AE1 in the third direction DR3. In a plan view, the second sub-bonding metal SAC2 may overlap the cathode electrode CE in the third direction DR3.

The first and second sub-bonding metals SAC1 and SAC2 may include the same metal material. The first and second sub-bonding metals SAC1 and SAC2 may be made of a combination of tin (Sn), silver (Ag), and copper (Cu).

The first sub-bonding metal SAC1 may be disposed on the first anode electrode AE1. In a plan view, the first sub-bonding metal SAC1 and the first anode electrode AE1 may overlap each other. The first sub-bonding metal SAC1 may be disposed on the first anode electrode AE1, and an Inter Metallic Compound (IMC) alloy may be formed in an area in which the first sub-bonding metal SAC1 and the first anode electrode AE1 are in contact with each other by irradiating laser.

The second sub-bonding metal SAC2 may be disposed on the cathode electrode CE. In a plan view, the second sub-bonding metal SAC2 and the cathode electrode CE may overlap each other. The second sub-bonding metal SAC2 may be disposed on the cathode electrode CE, and an Inter Metallic Compound (IMC) alloy may be formed in an area in which the second sub-bonding metal SAC2 and the cathode electrode CE are in contact with each other by irradiating laser.

Accordingly, the first light emitting element LD1 may be disposed on the first anode electrode AE1 and the cathode electrode CE without an adhesive layer, and be fixed on the pixel circuit layer PCL.

As the adhesive layer is not used, problems of a defect caused by a foreign matter sticking to the adhesive layer and deterioration of the adhesion of the adhesive layer may be solved.

As the adhesive layer between the pixel circuit layer PCL and the first light emitting element LD1 is removed, a problem (e.g., light leakage) due to a gap caused by the adhesive layer may be solved.

Each of the first and second sub-bonding metals SAC1 and SAC2 may serve as a reflective layer. As each of the first and second sub-bonding metals SAC1 and SAC2 is used as the reflective layer, light of the first light emitting element LD1 may be reflected upward (e.g., in the third direction DR3) so that the luminance of the display device DD may be increased.

In case that the first light emitting element LD1 is fixed using an adhesive layer, it is difficult to perform a repair process after the adhesive layer is cured. On the other hand, in case that the first light emitting element LD1 is fixed by forming the IMC alloy, using the first and second sub-bonding metals SAC1 and SAC2, the repair process may be performed by melting the IMC alloy.

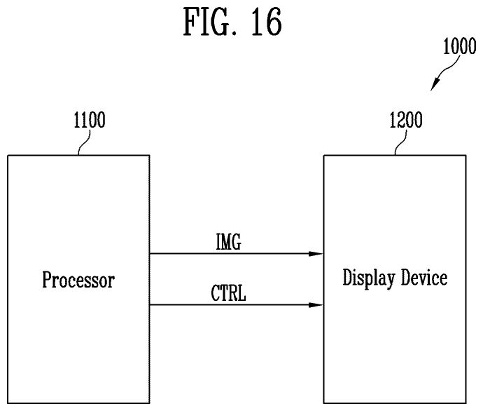

FIG. 16 is a schematic block diagram illustrating an embodiment of a display system (or electronic device).

Referring to FIG. 16, the display system 1000 may include a processor 1100 and a display device 1200.

The processor 1100 may perform various tasks and various calculations. The processor 1100 may include an Application Processor (AP), a Graphics Processing Unit (GPU), a microprocessor, a Central Processing Unit (CPU), and the like. The processor 1100 may be electrically connected to other components of the display system 1000 through a bus system to control the components of the display system 1000.

The processor 1100 may transmit an image data IMG and a control signal CTRL to the display device 1200. The display device 1200 may display an image (or images) based on the image data IMG and the control signal CTRL. The display device 1200 may be similarly configured to the display device DD described with reference to FIG. 1. The image data IMG and the control signal CTRL may be provided as the input image data IMG and the control signal CTRL, which are shown in FIG. 1, respectively.

The display system 1000 may include a computing system for providing an image display function, such as a smart watch, a mobile phone, a smartphone, a portable computer, a tablet personal computer (PC), a watch phone, an automotive display, a smart glass, a portable multimedia player (PMP), a navigation system, or an ultra mobile computer (UMPC). The display system 1000 may include at least one of a head mounted display (HMD) device, a virtual reality (VR) device, a mixed reality (MR) device, and an augmented reality (AR) device.

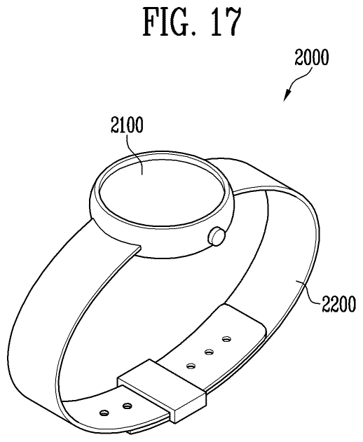

FIGS. 17 to 20 are schematic perspective views illustrating application examples of the display system shown in FIG. 16.

Referring to FIG. 17, the display system 1000 shown in FIG. 16 may be applied to a smart watch 2000 including a display part 2100 and a strap part 2200.

The smart watch 2000 may be a wearable electronic device. For example, the smart watch 2000 may have a structure in which the strap part 2200 is mounted on a wrist of a user. The display system 1000 and/or the display device 1200 may be applied to the display part 2100 so that image data including time information may be provided to a user.

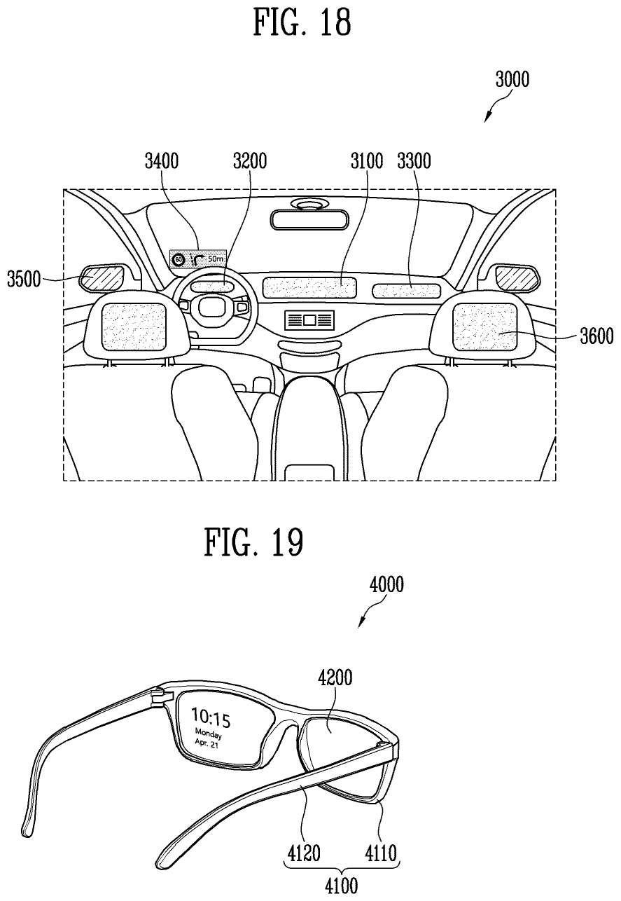

Referring to FIG. 18, the display system 1000 shown in FIG. 16 may be applied to an automotive display system 3000. The automotive display system 3000 may include a computing system provided at the inside/outside of a vehicle to provide image data.

For example, the display system 1000 and/or the display device 1200 may be applied to at least one of an infortainment panel 3100, a cluster 3200, a co-driver display 3300, a head-up display 3400, a side mirror display 3500, and a rear seat display 3600, which are provided in the vehicle.

Referring to FIG. 19, the display system 1000 shown in FIG. 16 may be applied to smart glasses 4000. The smart glasses 4000 may be a wearable electronic device which can be worn on the face of a user. For example, the smart glasses 4000 may be a wearable device for Augmented Reality (AR).

The smart glasses 4000 may include a frame 4100 and a lens part 4200. The frame 4100 may include a housing 4110 supporting the lens part 4200 and a leg part 4120 for allowing a user to wear the smart glasses 4000. The leg part 4120 may be connected to the housing 4110 through a hinge to be folded or unfolded with respect to the housing 4110.

A battery, a touch pad, a microphone, a camera, and the like may be built in the frame 4100. A projector for outputting light, a processor for controlling a light signal, and the like may be built in the frame 4100.

The lens part 4200 may be an optical member which allows light to be transmitted therethrough or allows light to be reflected thereby. For example, the lens part 4200 may include glass, transparent synthetic resin, and the like.

In order to enable eyes of the user to recognize visual information, the lens part 4200 may allow an image (or images) caused by a light signal transmitted from the projector of the frame 4100 to be reflected by a rear surface (e.g., a surface in a direction facing the eyes of the user) of the lens part 4200. For example, a user may recognize information including time, data, and the like, which are displayed on the lens part 4200. The projector and/or the lens part 4200 may be a kind of display device. For example, the display device 1200 may be applied to the projector and/or the lens part 4200.

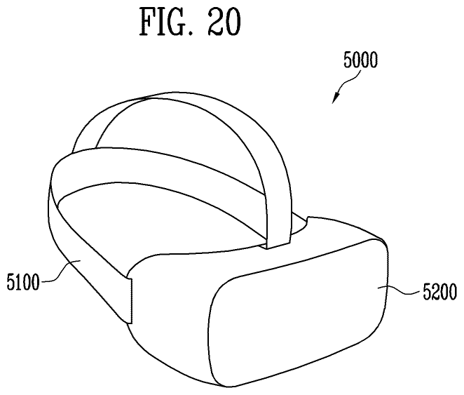

Referring to FIG. 20, the display system 1000 shown in FIG. 16 may be applied to a head mounted display device 5000.

The head mounted display device 5000 may be a wearable electronic device which can be worn on the head of a user. For example, the head mounted display device 5000 may be a wearable device for virtual reality (VR) or mixed reality (MR).

The head mounted display device 5000 may include a head mounted band 5100 and a display device accommodating case 5200. The head mounted band 5100 may be connected to the display device accommodating case 5200. The head mounted band 5100 may include a horizontal band and/or a vertical band, used to fix the head mounted display device 5000 to the head of a user. The horizontal band may surround a side portion of the head of the user, and the vertical band may surround an upper portion of the head of the user. However, embodiments are not limited thereto. For example, the head mounted band 5100 may be implemented in the form of a glasses frame, a helmet or the like.

The display device accommodating case 5200 may accommodate the display system 1000 and/or the display device 1200.

In other embodiments, the display system 1000 shown in FIG. 16 may be applied to, a mobile phone, a smartphone, a portable computer, a tablet personal computer (PC), a watch phone, a portable multimedia player (PMP), a navigation system, an ultra-mobile computer (UMPC), a virtual reality (VR) device, a mixed reality (MR) device, and an augmented reality (AR) device.

In the display device in accordance with the disclosure, a light emitting element is fixed to a pixel circuit layer without an adhesive layer, so that a problem caused by the adhesive layer can be solved, a luminance can be increased, and a repair process can be easily performed.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims.

What is claimed is:

1. A display device comprising:
a substrate; and
a display element layer disposed on the substrate,
wherein the display element layer includes:
an anode electrode and a cathode electrode;
a first bonding metal disposed between the anode electrode and the cathode electrode;
a first reflective electrode disposed on the anode electrode;
a second reflective electrode disposed on the cathode electrode;
a light emitting element including a first element electrode, a second element electrode, and a second bonding metal;
a first transparent electrode electrically connecting the first reflective electrode to the first element electrode; and
a second transparent electrode electrically connecting the second reflective electrode to the second element electrode to each other.

2. The display device of claim 1, wherein the first bonding metal and the second bonding metal overlap each other in a plan view.

3. The display device of claim 2, wherein the anode electrode, the cathode electrode, and the first bonding metal are spaced apart from each other.

4. The display device of claim 2, wherein the second bonding metal is disposed under the light emitting element, and
a metallic alloy is formed in an area in which the first bonding metal and the second bonding metal are in contact with each other.

5. The display device of claim 4, wherein the first bonding metal includes copper (Cu), and the second bonding metal includes a combination of tin (Sn), silver (Ag), and copper (Cu).

6. The display device of claim 5, wherein the display element layer is disposed on the substrate in a thickness direction,
the first element electrode and the second element electrode face in the thickness direction,
the first transparent electrode overlaps the first element electrode in a plan view, and
the second transparent electrode overlaps the second element electrode in a plan view.

7. The display device of claim 1, wherein the anode electrode, the cathode electrode, and the first bonding metal are disposed in a same layer, and
the anode electrode and the cathode electrode include a same conductive material.

8. An electronic device comprising a display device and a substrate, wherein the display device comprises:
a substrate; and
a display element layer disposed on the substrate,
wherein the display element layer includes:
an anode electrode and a cathode electrode;
a light emitting element including a first element electrode, a second element electrode, a first sub-bonding metal, and a second sub-bonding metal;
a first transparent electrode electrically connecting the anode electrode to the first element electrode; and
a second transparent electrode electrically connecting the cathode electrode to the second element electrode, and
the first sub-bonding metal and the second sub-bonding metal are disposed under the light emitting element.

9. The electronic device of claim 8, wherein, in a plan view, the first sub-bonding metal overlaps the anode electrode, and the second sub-bonding metal overlaps the cathode electrode.

10. The electronic device of claim 9, wherein a metallic alloy is formed in an area in which the first sub-bonding metal and the anode electrode are in contact with each other, and another metallic alloy is formed in an area in which the second sub-bonding metal and the cathode electrode are in contact with each other.

11. The electronic device of claim 10, wherein each of the first sub-bonding metal and the second sub-bonding metal includes a combination of tin (Sn), silver (Ag), and copper (Cu).

12. The electronic device of claim 11, wherein the display element layer is disposed on the substrate in a thickness direction,
the first element electrode and the second element electrode face in the thickness direction,
the first transparent electrode overlaps with the first element electrode in a plan view, and
the second transparent electrode overlaps with the second element electrode in a plan view.

13. The electronic device of claim 8, wherein the anode electrode and the cathode electrode are disposed in a same layer, and include a same conductive material.

14. A method of manufacturing a display device, the method comprising:
manufacturing a pixel circuit layer disposed on a substrate; and
manufacturing a display element layer disposed on the pixel circuit layer,
wherein the manufacturing of the display element layer includes;
patterning an anode electrode and a cathode electrode disposed on the pixel circuit layer;
patterning a first reflective electrode electrically connected to the anode electrode and a second reflective electrode electrically connected to the cathode electrode;
patterning a first bonding metal disposed between the anode electrode and the cathode electrode; and
disposing, on the pixel circuit layer, a light emitting element including a first element electrode, a second element electrode, and a second bonding metal.

15. The method of claim 14, wherein, in a cross-sectional view, the first bonding metal is disposed in a space in which the anode electrode and the cathode electrode are spaced apart from each other.

16. The method of claim 15, wherein, in a cross-sectional view, the anode electrode, the cathode electrode, and the first bonding metal are spaced apart from each other.

17. The method of claim 14, wherein the disposing of the light emitting element including the first element electrode, the second element electrode, and the second bonding metal on the pixel circuit layer includes:
forming the second bonding metal between the light emitting element and the first bonding metal.

18. The method of claim 17, further comprising:
irradiating laser between the first bonding metal and the second bonding metal; and
generating a metallic alloy in an area in which the first bonding metal and the second bonding metal are in contact with each other by irradiating the laser.

19. The method of claim 18, wherein the first bonding metal includes copper (Cu), and the second bonding metal includes a combination of tin (Sn), silver (Ag), and copper (Cu).

20. The method of claim 19, wherein the manufacturing of the display element layer further includes patterning a first transparent electrode electrically connected to the first reflective electrode and a second transparent electrode electrically connected to the second reflective electrode after the light emitting element is disposed on the pixel circuit layer.
